(19) United States
(12) Patent Application Publication
(10) Pub. No.: US 2010/0180950 A1
(43) Pub. Date: Jul. 22, 2010

(54) LOW-TEMPERATURE SURFACE DOPING/ALLOYING/COATING OF LARGE SCALE SEMICONDUCTOR NANOWIRE ARRAYS

(75) Inventors: Pu-Xian Gao, Coventry, CT (US); Paresh Shimpi, Willimantic, CT (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: University of Connecticut, Farmington, CT (US)

(21) Appl. No.: 12/618,689

(22) Filed: Nov. 13, 2009

Related U.S. Application Data
(60) Provisional application No. 61/205,811, filed on Jan. 23, 2009.
(60) Provisional application No. 61/199,314, filed on Nov. 14, 2008.

(51) Int. Cl. H01L 31/0296; H01L 21/40; H01L 29/12; H01L 33/28; H01L 31/00; H01L 21/46; B05C 3/02; B05C 11/00

(52) U.S. Cl. 136/265; 438/104; 257/43; 257/13; 136/252; 118/400; 118/58; 257/E29.068; 257/E33.021; 257/E21.47; 257/E21.482; 977/762

(57) ABSTRACT

A method and corresponding system for providing a uniform nanowire array including uniform nanowires composed of at least three elements is presented. An embodiment of the method includes growing an array of two-element nanowires, and thereafter uniformly doping or alloying each two-element nanowire, with respect to each other two-element nanowire, with at least one doping or alloying element through a wet chemical synthesis with a precursor solution, to produce the uniform array of nanowires composed of at least three elements. The two-element nanowire can include Zn and O, and the at least one doping or alloying element can be Mg, Cd, Mn, Cu, Be, Fe, and Co. Applications of the three-element nanowire array include solar cells and light emitting diodes with improved efficiencies over existing technologies.

### RELATED APPLICATION

This application claims the benefit of U.S. Provisional Application Nos. 61/205,811, filed on Jan. 23, 2009 and 61/199,314, filed on Nov. 14, 2008.

The entire teachings of the above applications are incorporated herein by reference.

### BACKGROUND OF THE INVENTION

Semiconducting ZnO has superior chemical and thermal stability as well as electronic and optoelectronic properties with a broad range of potential applications. For example, ZnO nanowires may be employed in a number of optoelectronic and display devices.

As an alloyed compound, ZnMgO is regarded as an ideal material for tunable ultraviolet optoelectronic devices. By alloying with MgO, a cubic structure with a direct band gap of 7.7 eV, the band gap of ZnO can be remarkably blue-shifted for realization of light-emitting devices operating in a wider wavelength range. However, prior art methods of achieving such an alloy have not been able to produce an alloy with nanoscale localized uniformity.

### SUMMARY OF THE INVENTION

According to example embodiments of the present invention, a method, and corresponding system, for providing a uniform nanowire array including uniform nanowires composed of at least three elements is presented. The method can include growing an array of two-element nanowires, and thereafter uniformly doping or alloying each two-element nanowire, with respect to each other two-element nanowire, with at least one doping or alloying element through a wet chemical synthesis with a precursor solution, to produce the uniform nanowire array of at least three-element nanowires.

Growing the array two-element nanowires can further include uniformly varying a characteristic of each two-element nanowire, in which the characteristic can be physical dimensions, processing time, temperature, packing density, energy band-gap, and/or composition of each two-element nanowire. Growing the array of two-element nanowires can also include a seeded or non-seeded growing. Further, growing the array of two-element nanowires can include performing a hydrothermal or solvathermal synthesis.

The uniform doping or alloying of each two-element nanowire can further include uniformly controlling a concentration and band-gap of each at least three element nanowire by varying a fabrication parameter. The fabrication parameter can be temperature, processing time, pH, and pressure. The uniform doping or alloying of each two-element nanowire can also include uniformly controlling a concentration of each element of each at least three-element nanowire. The uniform doping or alloying of each two-element nanowire can also include doping or alloying each two element nanowire in a manner where each at least three-element nanowire is uniform with respect to a radial cross-section.

The wet chemical synthesis can be a hydrothermal or solvathermal synthesis performed at a temperature of less than 300° C. In one embodiment, the hydrothermal or solvathermal synthesis can be performed at a temperature in a range of between about 100° C. and about 200° C. In a preferred embodiment, the two-element nanowire comprises Zn and O, and the at least one doping or alloying element includes at least one element from a group consisting of Mg, Cd, Mn, Cu, Be, Fe, and Co. In another embodiment, the two-element nanowire comprises Cu and O, and the at least one doping or alloying element includes at least one element selected from a group consisting of Zn, Mg, Cd, Mn, Be, Fe, and Co. In yet another embodiment, the two-element nanowire comprises Cd and O, and the at least one doping or alloying element includes at least one element selected from a group consisting of Mg, Zn, Mn, Cu, Be, Fe, and Co. In still another embodiment, the two-element nanowire comprises Mg and O, and the at least one doping or alloying element includes at least one element selected from a group consisting of Zn, Cd, Mn, Cu, Be, Fe, and Co. In yet another embodiment, the two-element nanowire comprises Fe and O, and the at least one doping or alloying element includes at least one element selected from a group consisting of Mg, Zn, Mn, Cu, Be, Cd, and Co. In still another embodiment, the two-element nanowire comprises Be and O, and the at least one doping or alloying element includes at least one element selected from a group consisting of Zn, Cd, Mn, Cu, Mg, Fe, and Co. In yet another embodiment, the two-element nanowire comprises Mn and O, and the at least one doping or alloying element includes at least one element selected from a group consisting of Mg, Zn, Cd, Cu, Be, Fe, and Co.

The process of providing the uniform nanowire array can further include annealing the uniform nanowire array of at least three-element nanowires. Annealing the at least three element nanowire array can be performed at a temperature in a range of between about 200° C. and about 1000° C., for a time period in a range of between about 5 minutes and about 10 hours.

In another embodiment, a system for providing a uniform nanowire array includes a first module configured to grow an array of two-element nanowires, a second module configured to prepare a precursor solution including at least one doping or alloying element and a base, and a third module configured to provide a uniform nanowire array by using a wet chemical synthesis with the precursor solution, thereby providing an at least three-element nanowire array including a uniform composition distribution.

In yet another embodiment, a method of producing a uniform nanowire array includes uniformly doping or alloying each two-element nanowire of a two-element nanowire array with at least a third element through a wet chemical synthesis with the precursor solution, thereby forming an array of at least three-element nanowires.

In still another embodiment, a uniform nanowire array comprises a plurality of nanowires including at least three elements, each nanowire being uniform with respect to a concentration of the at least three-elements in a radial cross section.

Another example embodiment of the invention is directed to a uniform nanowire array, said array produced by the process of growing a uniform array of two-element nanowires, mixing a solution of chemical precursors including at least one doping or alloying element and a base, disposing the array of two-element nanowires in the solution, and heating the disposed array of two-element nanowires in a manner uniformly doping or alloying the array of two-element nanowires with the at least one doping element, thereby forming a uniform array of at least three-element nanowires.

In another embodiment, a solar cell device includes at least one layer including a uniform three-element nanowire array having uniform three-element nanowires with respect to each other nanowire in terms of chemical composition. In one embodiment, the elements include Zn, O, and Mg.

In yet another embodiment, an electronic device includes a plurality of nanowires defining a junction of the device, each nanowire including a uniform concentration of at least three elements. The electronic device can further include leads configured to carry electrons to or from the junction to enable the electronic device to convert electrons to photons or photons to electrons. The electronic device can be an optoelectronic device.

Embodiments of the invention have many advantages over current related technologies, such as low cost, large yield, environmental friendliness, and low reaction temperature, enabling the production of improved optoelectronic and display devices.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1 is a set of images that illustrates a low magnification scanning electron microscope (SEM) image of (a) ZnO nanowires (b) ZnMgO nanowires (c) a 30° tilt view of ZnMgO nanowires, and (d) a typical energy dispersive x-ray spectroscopy (EDXS) spectrum of ZnMgO nanowires corresponding to the circled region in the inset of (c).

FIG. 2 is a pair of data plots that illustrates (a) x-ray diffraction (XRD) spectra of ZnO nanowire arrays, (b) illustrates (002) peak of ZnMgO nanowires showing −0.1° shift compared to that from ZnO nanowire arrays.

FIG. 3 is a set of plots that illustrates (a) a pair of typical low magnification bright field (top) and dark field (bottom) transmission electron microscope (TEM) images of a ZnMgO nanowire with [0001] growth direction; (b) the corresponding selected area electron diffraction pattern; (c) Left side: a low magnification high resolution TEM image showing the surface region of ZnMgO nanowire surrounded by an amorphous layer possibly made of MgO; and Right side: a high resolution TEM lattice image indicating the lattice spacing of [0001] planes of ZnMgO; (d) a typical EDX spectrum acquired from a single ZnMgO nanowire in TEM; (e) a typical low magnification TEM image of ZnMgO nanowire with [01 1̅0] growth direction; (f) the corresponding selected area electron diffraction pattern; and (g) a TEM image indicating the local region of a ZnMgO nanowire with clear dendritic branches as indicated by arrows.

FIG. 4 is a set of plots and images that illustrates a series of scanning TEM (STEM) analysis results, including (a) an STEM image of a single ZnMgO nanowire ˜1 μm long and ˜100-200 nm wide, the dotted line indicating an elemental line scan across the axis of the nanowire; (b) a collected EDX spectrum from the line scanning across the ZnMgO nanowire axis; (c), (d) and (e) the line profiles of Mg, O, and Zn respectively; (f), (g) and (h) the elemental chemical maps of Mg, O, and Zn, respectively, where all scale bars are 200 nm.

FIG. 5 is a set of plots that illustrates a typical XPS spectrum of ZnMgO nanowire arrays on Si substrate, including insets (a) Zn LMM spectrum with oxygen; and (b) Mg spectrum indicating the existence of MgO.

FIG. 6 is a set of plots that illustrates photoluminescence spectra of ZnMgO nanowire arrays compared to that of ZnO nanowire arrays at a) room temperature (RT), and b) at 40 K.

FIG. 7 illustrates a two-step (steps a) and b)) growth model of ZnMgO nanowire arrays.

FIG. 8 is a table that illustrates alternative materials which can be used in the fabrication of the nanowire arrays.

FIG. 9 is a set of images and a table that illustrates low magnification a) and high magnification b) SEM images of tilt-view as-grown ZnMgO nanowires; and low magnification c) and high magnification d) top-view ZnMgO nanowires after 900° C. annealing for 5 minutes; e) energy dispersive X-ray spectrum of ZnMgO nanowires after 900° C. annealing for 5 minutes, and corresponding elemental analysis.

FIG. 10 is a set of images that illustrates transmission electron microscopy images and the corresponding selected-area electron diffraction (SAED) patterns of a) as-grown ZnMgO nanowire; b) ZnMgO nanowire grown along [01 1̅0] after 400° C. annealing for 30 minutes; and c) top-view ZnMgO nanowires after 900° C. annealing for 5 minutes.

FIG. 11 is a set of images that illustrates transmission electron microscopy images and the corresponding selected-area electron diffraction (SAED) patterns of a) ZnMgO nanowire after 400° C. annealing for 30 minutes; b) ZnMgO nanowires after 800° C. annealing for 5 minutes; and c) high resolution TEM image of the surface region of ZnMgO nanowire after 800° C. annealing for 5 minutes.

FIG. 12 is a set of images that illustrates an epitaxial Mg-rich oxide structure formed over ZnMgO nanowire surface after 900° C. annealing for 5 minutes including a) transmission electron microscopy images and the corresponding selected-area electron diffraction (SAED) patterns of ZnMgO nanowire after 900° C. annealing for 5 minutes; b) high resolution TEM image of the surface region of ZnMgO nanowire after 900° C. annealing for 5 minutes; and c) FFT selected area electron diffraction pattern corresponding to the boxed region in b).

FIG. 13 is a plot that illustrates room temperature photoluminescence spectra collected from as-grown ZnO nanowire arrays (labeled as ‘ZnO’); as-grown ZnMgO nanowire arrays (labeled as ‘ZMO’); and ZnMgO nanowire arrays after 400° C. annealing for 30 minutes (labeled as ‘ZMO400C30 min’).

FIG. 14 is a set of plots that illustrates a) room temperature photoluminescence spectra collected from ZnMgO nanowire arrays after 400° C. annealing for 30 minutes (labeled as ‘ZMO400C30 min’); ZnMgO nanowire arrays after 600° C. annealing for 30 minutes (labeled as ‘ZMO600C30 min’); and ZnMgO nanowire arrays after 700° C. annealing for 30 minutes (labeled as ‘ZMO700C30 min’); and b) Room temperature photoluminescence spectra collected from ZnMgO nanowire arrays after 900° C. annealing for 5 minutes (labeled as ‘ZMOannealed900C’);

FIG. 15 is a mechanical/electrical schematic diagram that illustrates an optically pumped or electrically driven multi-spectrum light emission diode (LED) junction between n-type ZnO/n-ZnMgO/MgZnO/MgO and p-Si that forms a multiple band-offset heterojunction diode, leading to a different emission light spectrum wavelength (variable ν₁) upon energetic optical (hν) or electrical excitation (E=hν), where ν>ν₁.

FIG. 16 is a set of schematic diagrams that illustrates two types of heterojunction nanowire building blocks for fabricating solar cells where the solar radiation input is from the bottom electrode, including (a) ZnO/MgZnO/MgO/CuₓO or ZnO/CuZnO/Cu₂O gradient nanowire arrays; (b) ZnO/MgZnO/MgO/Cu₂O, or ZnO/CuZnO/Cu₂O gradient nanodendrite arrays; (c) a prototype device schematic for gradient nanowire solar cell arrays (x=1, 2); in which cases, for example, when the nanowire/dendrite array is sufficiently dense, the PMMA insulation layer or dielectric space for supporting the device structure can be omitted.

FIG. 17 is a set of schematic diagrams that illustrates two types of heterojunction nanowire building blocks for fabricating solar cells where the solar radiation input is from the top electrode, including (a) ZnO/MgZnO/MgO/CuₓO or ZnO/CuZnO/Cu₂O gradient nanowire arrays; (b) ZnO/MgZnO/MgO/Cu₂O, or ZnO/CuZnO/Cu₂O gradient nanodendrite arrays; and (c) a prototype device schematic for gradient nanowire solar cell arrays (x=1, 2).

### DETAILED DESCRIPTION OF THE INVENTION

A description of example embodiments of the invention follows.

As an alloyed compound, ZnMgO is regarded as an ideal material for tunable ultraviolet optoelectronic devices. By alloying with MgO, a cubic structure with a direct band gap of 7.7 eV, the band gap of ZnO can be remarkably blue-shifted for the realization of light-emitting devices operating in a wider wavelength range Practically, the similar ionic radii of Mg²⁺ and Zn²⁺ make it feasible to achieve the substitutional replacement of Zn²⁺ with Mg²⁺. One-dimensional (1D) nanostructures of ZnMgO such as nanowires (NWs), nanorods, nanopillars, and ZnO/ZnMgO nanoscale heterostructures, along an axial or radial direction have been mostly fabricated using vapor phase deposition techniques such as metal-organic vapor phase epitaxy (MOVPE), pulsed laser deposition (PLD), molecular beam epitaxy (MBE), RF magnetron co-sputtering, thermal evaporation, and vapor phase transport. See Ohtamo, A.; Kawasaki, M.; Ohkubo, I.; Koinuma, H.; Yasuda, T.; Segawa, Y. Appl. Phys. Lett. 1999, 75, 980; see Makino, T.; Chia, C. H.; Tuan, N. T.; Sun, H. D.; Segawa, Y.; Kawasaki, M.; Ohtomo, A.; Tamura, K.; Koinuma, H. Appl. Phys. Lett. 2000, 77, 975; see Park, W. I.; Yi, G.; Jang, H. M. Appl. Phys. Lett. 2001, 79, 2022; see Yang, W.; Vispute, R. D.; Choopum, S.; Sharma, R. P.; Venkatesan, T.; Shen, H. Appl. Phys. Lett. 2001, 78, 2787; see Krishnamoorthy, S.; Iliadis, A. A.; Inumpudi, A.; Supab, C.; Vispute, R. D.; Venkatesan, T. Solid State Electron. 2002, 46, 1633; see Kling, R.; Kirchner, C.; Gruber, T.; Reuss, F.; Waag, A. Nanotechnology 2004, 15 1043; see Lorenz, M.; Kaidashev, E. M.; Rahm, A.; Nobis, T.; Lenzer, J.; Wagner, G.; Spemann, D.; Hochmuth, H.; Grundmann, M. Appl. Phys. Lett. 2005, 86, 143113; see Heo, Y. W.; Kaufman, M.; Pruessner, K.; Norton, D. P.; Ren, F.; Chisholm, M. F.; Fleming, P. H. Solid State Electron. 2003, 47, 2269; see Kar, J. P.; Jeong, M. C.; Myoung, J. M.; Lee, W. K. Mater. Sci. and Eng. B 2008, 147, 74; see Wang, G.; Ye, Z.; He, H.; Tang, H.; Li, J. J. Phys D: Appl. Phys. 2007, 40, 5287; see Hsu, H. C.; Wu, C. Y.; Cheng, H. M.; Hsieh, W. F.; Appl. Phys. Lett. 2006, 89, 013101.

In contrast to vapor phase techniques, much less success has been achieved for the growth of ZnMgO NWs using wet chemical synthesis approaches. This is largely due to a significant difficulty in alloying Mg into ZnO lattices at the typically much lower processing temperatures of the vapor phase approaches. However, wet chemical methods such as a hydrothermal synthesis process have several unique advantages, which include low cost, large yield, environmental friendliness and low reaction temperature.

Recently, Gayen et al., reported a successful synthesis of ZnMgO nanowires on a glass substrate using hydrothermal synthesis, but the randomness of the achieved ZnMgO nanowires hinders their use for device fabrications. See Gayen, R. N.; Das, S. N.; Dalui, S.; Bhar, R.; Pal, A. K. Journal of Crystal Growth, 2008, 310, 4073. Furthermore, this reported result did not investigate the nanoscale local distribution of Mg in each individual ZnMgO nanowire, a serious practical issue for future applications.

According to example embodiments, a successful and reliable surface localized alloying induced large scale ZnMgO NW arrays based on a low temperature multi-step sequential hydrothermal synthesis on ZnO seeded solid Si substrate is presented.

Large scale ZnMgO nanowire arrays have been successfully synthesized on Si substrates using the multi-step sequential hydrothermal synthesis at low temperature for the first time. X-ray diffractometry (XRD), transmission electron microscopy (TEM), scanning transmission electron microscopy (STEM), and X-ray photoelectron spectroscopy (XPS) were systematically and successfully carried out to confirm and elaborate the localized Mg surface alloying process into the ZnO nanowire arrays. Both room temperature and low temperature (40 K) photoluminescence results revealed an enhanced and blue-shifted near-band-edge (NBE) UV emission for the ZnMgO nanowires compared to those of the pure ZnO nanowire arrays. This enhancement might be due to 155° C. solution-based process and the amorphous MgO dendrite branches surrounding the ZnMgO nanowires. The specific template of densely-packed ZnO nanowire arrays was suggested to be instrumental in enabling a second-step surface localized alloying of Mg into ZnO lattices. The results reported here open up a new avenue for low cost and low temperature elemental doping/alloying of nanowire arrays of functional oxides and compound semiconductors.

According to a specific embodiment, large scale ZnMgO nanowire arrays have been successfully synthesized on Si substrates using a multi-step sequential hydrothermal synthesis at low temperature for the first time. Based on ZnO nanowire arrays synthesized at 80° C., the successful surface localized alloying of Mg into the ZnO lattices has been achieved through a secondary hydrothermal process at 155° C. in one particular experiment. The X-ray diffraction analysis indicated a ˜0.1° shift of 2θ in (002) peak of ZnMgO nanowires compared to that of ZnO nanowires, suggesting a successful alloying of Mg into ZnO nanowire lattices after the multi-step low-temperature synthesis process. The transmission electron microscopy, scanning transmission electron microscopy, and X-ray photoelectron spectroscopy were systematically carried out. The results further proved that a successful surface localized Mg alloying process was achieved on the densely packed ZnO nanowire arrays during the solution-based low temperature process. Both room temperature and low temperature (40K) photoluminescence results revealed an enhanced and blue-shifted near-band-edge UV emission for the ZnMgO nanowires compared to that of the pure ZnO nanowire arrays. The specific template of densely-packed ZnO nanowire arrays was suggested to be crucial in enabling the second-step surface localized alloying of Mg into ZnO lattices. This result opens up a new avenue for low cost and low temperature elemental doping/alloying of nanowire arrays of functional oxides and compound semiconductors, which enables new nano-electronics and nano-optoelectronics applications. In order to clarify the surface Mg doping and alloying process, and at the same time investigate the surface coating process of MgO on alloyed ZnO nanowires, a post thermal annealing study was also systematically carried out on the low-temperature solution-processed MgO/ZnMgO nanowire arrays.

### Fabrication of Nanowires:

In example embodiments, surface doping, alloying and coating of MgO/ZnMgO/ZnO nanowire arrays have been carried out by low temperature hydrothermal synthesis on substrates. Doping typically includes incorporating a concentration of the third element, such as, for example, Mg, below about 1 atomic percent, while alloying can include incorporating higher concentrations. ZnMgO nanowire arrays have been grown on Si (100) substrate by low temperature hydrothermal synthesis. Alternative substrates, include Al₂O₃, glass, and flexible substrates including polymer substrates such as polyimide, as well as other substrates that are chemically inert under the conditions employed in hydrothermal synthesis. Hydrothermal synthesis conditions include a pressure that is typically between about 1 bar and about 2 bar, preferably about 1.5 bar, and a temperature below about 300° C. Hydrothermal synthesis includes water as the solvent, while solvathermal synthesis can include other solvents, such as, for example, methanol or ethanol. The Si (100) substrate was seeded by ZnO nanoparticles using a sol-gel process. See Pacholski, C.; Kornowski, A.; Weller, H. Angew. Chem. Int. Ed. 2002, 41(7), 1188; see D. L. Jian, P. X. Gao, W. J. Cai, B. S. Allimi, S. P. Alpay, Y. Ding, Z. L. Wang, C. Brooks, “Synthesis, Characterization, and Photocatalytic Properties of ZnO/(La,Sr)CoO₃ Composite Nanorod Arrays,” J. Mater. Chem., 2009, 19, 970; see P. Shimpi, P. X. Gao, D. Goberman, Y. Ding, “Low temperature synthesis of large scale ZnO/ZnMgO/MgO composite nanowire arrays”, Nanotechnology, 2009, 20 125608. ZnO nanoparticles of about 10 nm to about 50 nm in size can be obtained by the sol-gel process by controlling the processing time, temperature, pH, and precursor concentration. For the growth of ZnMgO nanowires, a multi-step sequential procedure was carried out.

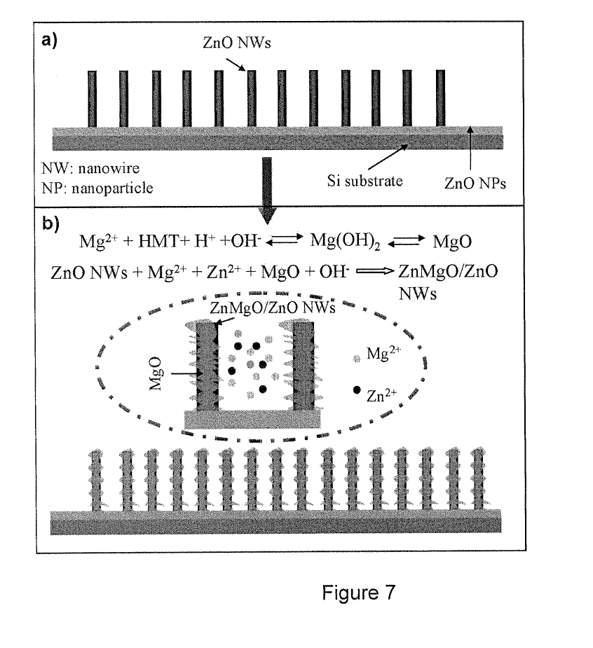

First, the ZnO nanowire arrays were grown by putting the ZnO nanoparticle-seeded substrate in an aqueous solution of Zn(NO₃)₂.6H₂O and hexamethylenetetramine (HMT) in 1:1 ratio at 80° C. for 4 hours. See Gao, P. X.; Song, J.; Liu, J.; Wang, Z. L. Adv. Mater. 2007, 19, 67. The processing conditions for the first step can include a temperature from about 50° C. to about 95° C., and a processing time from about 30 minutes to a few days, preferably from about 30 minutes to about 24 hours. The process can employ other Zn-containing salts, such as, for example, ZnCl₂. Hexamethylenetetramine is a preferred weak base, but other weak bases, such as, for example, ammonium hydroxide, or, less desirably, diluted sodium hydroxide, can be used to achieve a pH of about 4-10, preferably about 5-9, and most preferably about 6-8. A longer processing time yields larger nanowires, with a diameter from a few nanometers to a few microns, and a length in a range from tenths of nanometers to tens of microns. The packing density of nanowires on the substrate, illustrated in FIG. 7, can be controlled by setting the distance between adjacent nanowires to be in a range of about 15 nm to about 10 μm, preferably in a range of about 100 nm to about 500 nm, to enable growth and alloying by diffusion of Zn²⁺ and Mg²⁺ ions.

Second, the substrate coated with ZnO nanowires was immersed into the aqueous solution of Zn(NO₃)₂.6H₂O, HMT and Mg(NO₃)₂.6H₂O in a ratio of 1:1:2 at 155° C. for 4 hours. The processing conditions for the second step can include a temperature from about 100° C. to about 200° C., and a processing time from about 5 minutes to several days, preferably from about 5 minutes to about 10 hours. Finally, the substrate containing the ZnMgO nanowires was rinsed with de-ionized water and dried at 80° C. overnight. The drying temperature can be in a range of about 50° C. to about 200° C. By employing this process, the chemical concentration of the three elements can be uniform with respect to each nanowire in the array, thereby preventing the randomness problems associated with the findings of Gayen et al. Furthermore, by controlling the temperature, concentration, and duration time of the process, different level of doping, alloying and coating can be achieved across each nanowire radial cross section, resulting in either completely alloyed MgO/ZnMgO composite nanowires, or partially alloyed MgO/ZnMgO/ZnO nanowires.

It should be appreciated that various characteristics may be uniformly varied during fabrication of the ZnO or ZnMgO nanowire arrays. For example, characteristics can include physical dimension, packing density, energy band-gap, and/or chemical composition of each nanowire in the array. These variations may be provided by varying temperature, processing time, pH, and/or pressure during fabrication.

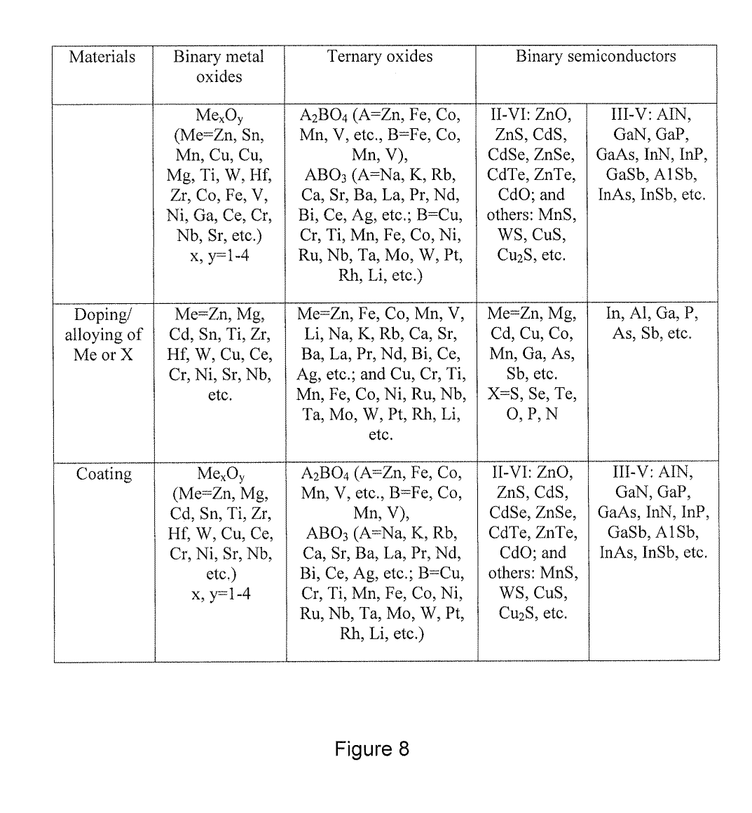

It should further be appreciated that the nanowire array may comprise a variety of other elements, examples of which are illustrated in the table of FIG. 8.

### Characterization & Analysis:

According to example embodiments, the chemical composition, morphology and orientation characterization were carried out using JEOL 6335F field emission scanning electron microscope (FESEM) equipped with energy dispersive X-ray spectroscopy (EDXS). The microstructure and chemical characterization of ZnMgO nanowires was conducted using a Philip E420 transmission electron microscope (TEM), a JEOL 4000X TEM, and a Tecnai T12 scanning transmission electron microscopy (STEM) coupled with the EDXS. The X-ray diffraction (XRD) patterns were measured using BRUKER AXS D5005 (Cu Kα radiation, λ=1.540598 Å). The chemical composition and valence states of the grown nanowires were further examined using X-ray photoelectron spectroscopy (XPS) conducted on a Phi Model 4-548 twin anode X-ray source with a Phi 255-GAR electron analyzer. The room and low temperature photoluminescence spectroscopy was conducted using a LiCONiX He—Cd UV laser source at 325 nm with 20 mW output power. A photomultiplier tube with a GaAs photocathode was used as a detector. For low temperature measurement, a cyrogenics helium compressor was used at a pressure of ˜3×10⁻⁵ torr with a Danielson turbo pump. The X-ray diffraction results described below were analyzed by methods well known in the art of X-ray crystallography.

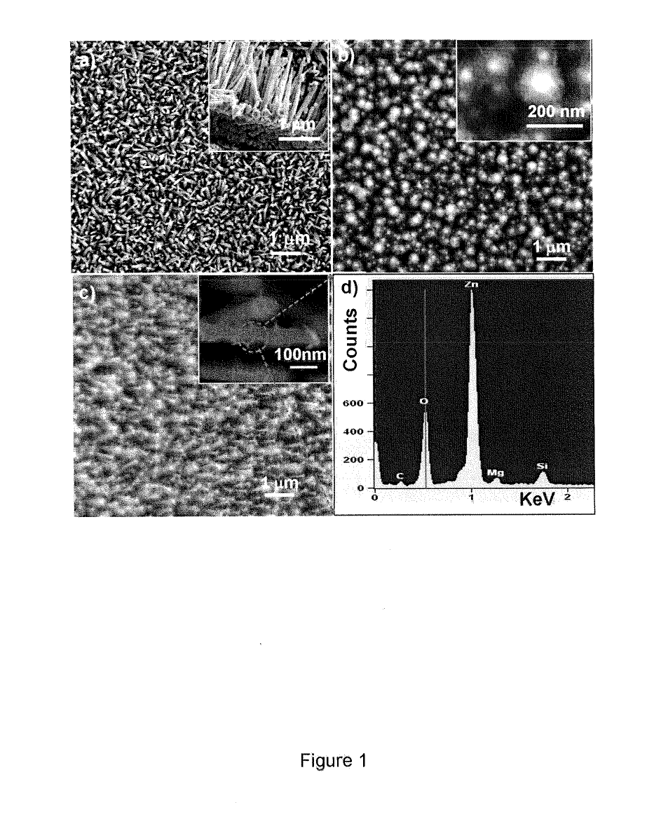

FIG. 1a is a typical low magnification scanning electron microscope (SEM) image of pure ZnO nanowires grown on a ZnO seeded Si (100) substrate after the first step hydrothermal process. As seen in FIG. 1a, the ZnO nanowires are uniformly grown vertically all over the substrate with a length of ˜1-1.5 μm and a diameter ˜90-100 nm.

FIG. 1b shows the top view of the ZnMgO nanowires after the second-step of the hydrothermal process. In FIG. 1b, ZnMgO nanowires look like star-shaped nanostructure arrays. To have a clear view of the morphological change after the two-step hydrothermal process, a 30° tilt-view was taken, as seen in FIG. 1c. It is clear that the nanowires were intact after the second-step processing and kept vertically aligned.

As demonstrated by FIG. 1c, it is apparent that ZnMgO nanowires have a dendrite-like morphology, whose branches distribute across the width of each individual nanowire along the nanowire axis. The dimensionality of the nanowires was maintained at ˜100 nm in diameter and ˜1-1.5 μm in length after the second step hydrothermal process.

FIG. 1d displays an energy dispersive x-ray (EDX) spectrum corresponding to the circled area in the inset of FIG. 1c, indicating that 3.62 atomic percent (at. %) of Mg is present in the local nanowire region. Across the whole substrate, an average of ˜4.0 at. % of Mg has been revealed using energy dispersive x-ray spectroscopy (EDXS). The carbon and silicon peaks are contributed by the possible contamination during sample preparation and the Si substrate respectively.

To find the structure variation of the grown ZnMgO nanowire arrays after the two-step process compared to the pure ZnO nanowire arrays, x-ray diffraction (XRD) analysis has been carried out.

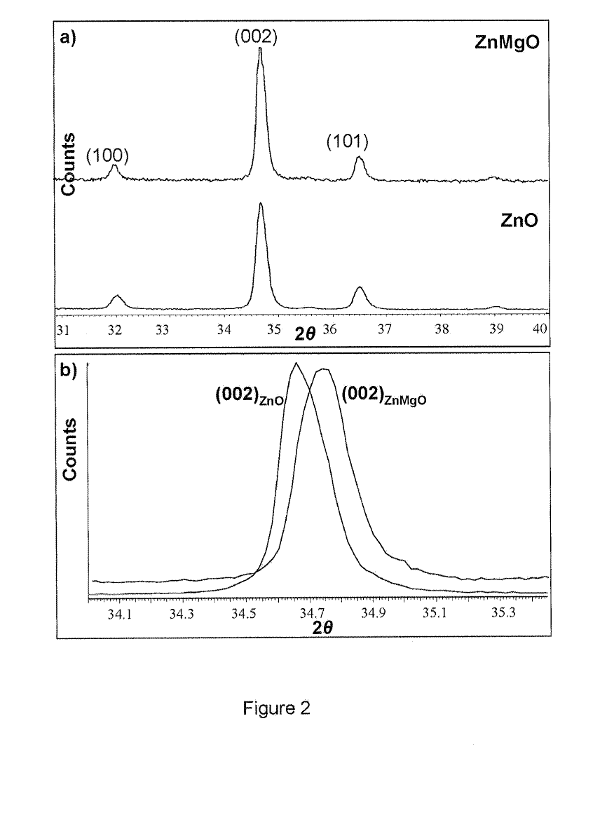

FIG. 2a shows two XRD spectra, where the top spectrum corresponds to ZnMgO nanowire arrays after the two-step hydrothermal process, and the bottom spectrum corresponds to ZnO nanowire arrays obtained after the first step hydrothermal process. It is clearly seen that the ZnMgO spectrum is very similar to that of the ZnO, with major peaks in planes (100), (002) and (101), which suggests a similar wurtzite crystal structure for ZnMgO nanowires. The strongest peak is seen at (002) corresponding to the c plane of wurtzite structured ZnMgO.

Additionally, no extra peaks are observed in the sample, thereby indicating a rather uniform deposition of ZnMgO nanowires with no detectable impurities. After careful examination and comparison of these two spectra, it is found that the major peak (002) in ZnMgO nanowire arrays has shifted to ˜0.1° higher 2θ angle compared to that of ZnO nanowire arrays as shown in FIG. 2b. This strongly indicates a successful substitution of the smaller Mg²⁺ ion (a radius of 0.057 nm) for the larger Zn²⁺ ion (a radius of 0.060 nm) in the ZnO nanowires after the two-step hydrothermal process with a designed intention to alloy Mg into the ZnO lattice. See Shannon, R. D. Acta Cryst. 1976, A32, 751.

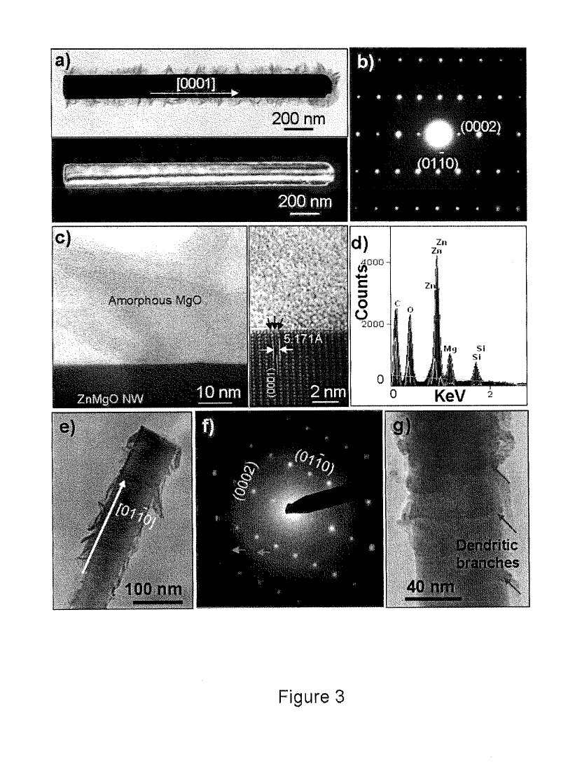

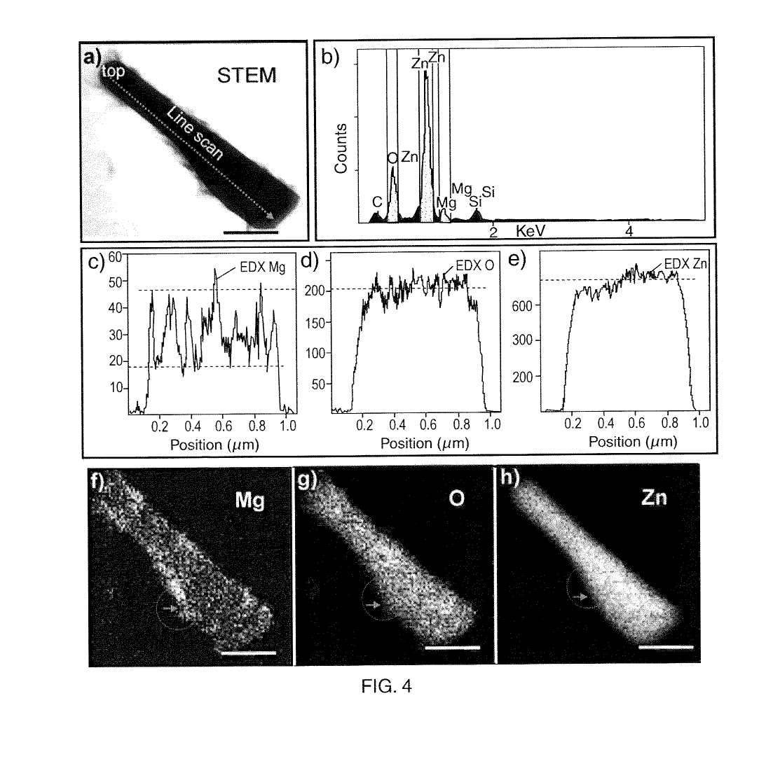

It is worth noting that these XRD results were acquired using carefully calibrated X-ray diffractometers, thus eliminating the possible calibration errors at the beginning of the measurements. This suggests the success of Mg alloying process through a two-step hydrothermal synthesis, which is further confirmed using the following transmission electron microscopy (TEM) and scanning transmission electron microscopy (STEM) characterization and analysis in FIGS. 3 and 4 respectively. Under the TEM, three types of ZnMgO nanowires were observed with growth directions along [0001] (FIGS. 3a-c), [01 1̅0] (FIGS. 3e-g) and [2 1̅1̅0], the three typical fast growth directions of ZnO nanowires. See Wang, Z. L.; Kong, X. Y.; Ding, Y.; Gao, P. X.; Hughes, W. L.; Yang, R.; Zhang, Y. Adv. Funct. Mater. 2004, 14, 943; see¹ Gao, P. X.; Wang, Z. L. J. Appl. Phys. 2005, 97, 044304; see¹ Xi, Y.; Hu, C. G.; Han, X. Y.; Xiong, Y. F.; Gao, P. X.; Liu, G. B. Solid State Comm. 2007, 141, 506.

FIG. 3a illustrates a pair of typical TEM bright field (BF, top) and corresponding dark field (DF, bottom) images of a dendrite-like ZnMgO nanowire ˜200 nm wide. The DF image in the bottom of FIG. 3a revealed a sharp interface between the surface dendrite-like branches and the core ZnMgO nanowire.

The nanowire has an axial growth direction along [0001], which was confirmed by the selected area electron diffraction (SAED) pattern shown in FIG. 3b. The SAED pattern of ZnMgO nanowire exhibits a single-crystalline characteristic similar to that of ZnO nanowire, suggesting uniformly fabricated ZnMgO nanowires based on the grown ZnO nanowires obtained in the first-step hydrothermal process.

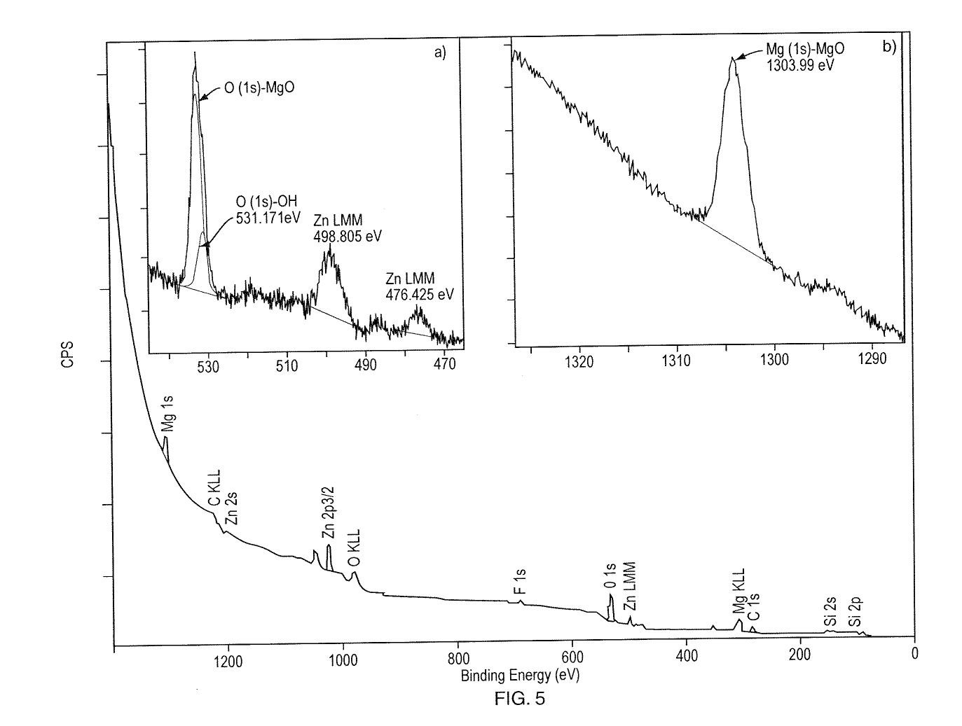

To reveal the atomic structures of the dendrite-like ZnMgO nanowires, high resolution. TEM (HRTEM) images were recorded in FIG. 3c. The left-side HRTEM image in FIG. 3c displays the surface region of ZnMgO nanowire with a surrounding amorphous layer possibly made of MgO (confirmed in the XPS results shown in FIG. 5). See Gayen, R. N.; Das, S. N.; Dalui, S.; Bhar, R.; Pal, A. K. Journal of Crystal Growth, 2008, 310, 4073. The ZnMgO nanowire has kept abruptly sharp surface lattices, which were clearly revealed in the right side HRTEM image of FIG. 3c. The HRTEM image indicates that the lattice spacing of (0001) planes is ˜2.586 Å, ˜0.0185 Å smaller than 2.6045 Å in the standard pure ZnO (0001) lattice spacing. This proved a successful surface alloying of Mg into ZnO lattices. The TEM EDXS data shown in FIG. 3d indicate the presence of ˜3.92 at. % Mg in the ZnMgO nanowires.

FIG. 3e is a typical TEM bright field image of the dendrite-like ZnMgO nanowire grown along [01 1̅0], as confirmed by the SAED pattern shown in FIG. 3f, where the [01 1̅0] and [0002] spots are indicated. It is consistent with the SEM observation in FIG. 1c, the dendrite-like structures passing across the width of the nanowire.

In FIG. 3f, weak diffusive ring patterns, indicated by arrowheads, revealed the amorphous structure of surface dendrite branches surrounding the single-crystalline ZnMgO nanowire as confirmed by the bright diffraction spots.

FIG. 3g shows the higher magnification image of ZnMgO nanowires with dendrite-like structure clearly passing across the nanowires as indicated by arrows with intervals of ˜0.05 μm.

To clarify the surface alloying process, a series of STEM chemical analysis measurements were carried out through an STEM line profile scanning and an elemental mapping. FIG. 4a shows a typical STEM image of a single dendrite-like ZnMgO nanowire, which is ˜1 μm long, ˜100 nm wide on top and ˜200 nm wide on bottom. The composition distribution was obtained at a single nanowire level by using the EDXS line scanning from the top to the bottom, as indicated by the dotted line in FIG. 4a. The collected EDXS signal was recorded in FIG. 4b, where ˜4-5 at. % of Mg was shown to be present. The line profiles of Mg, O, and Zn are shown in FIGS. 4c, d, and e, respectively. The Mg concentration peaks are at the interval of 0.15 μm, 0.1 μm or 0.08 μm throughout the ˜1 μm long nanowire. This feature indicates that the Mg is present across the axis of the nanowire with a certain fluctuation in EDXS counts between ˜20-50, as shown in FIG. 4c. FIGS. 4d and 4e show that the Zn and O are uniformly distributed across the length of the nanowire.

FIGS. 4f-h display the elemental chemical maps of Mg, O, and Zn, respectively. The uniformities of the Zn and O are similar on the ZnMgO nanowire. From the Mg map in FIG. 4f, it can be seen that the Mg has a higher concentration at the edge compared to non-uniform concentration across the width of the nanowire. Together with the line-scanning results in FIGS. 4c-e, it can be concluded that the ZnMgO nanowire has Mg distributed across the width and edge of the nanowire.

Furthermore, it is revealed that the Mg and O contours in FIGS. 4f and 4g conform to the contour of the STEM image in FIG. 4a with the dendrite-like branches, as indicated by the circles in FIGS. 4f-h, while the Zn map retains a very sharp surface profile/contour. Therefore, the surface amorphous dendrite branches should be of MgO related structure, as will be confirmed by the following XPS result shown in FIG. 5. The XPS results in FIG. 5 shows the photoelectron peaks of Zn, Mg, O, C, Si, F, and the Auger peaks of Zn LMM, O KLL, C KLL, and Mg KLL. Three strong peaks located at 532.699, 1022.66 and 1045.69 eV are due to O(1s), Zn(2p_{3/2}), and Zn(2p_{1/2}) binding energies for ZnO respectively. The binding energy of the Mg (1s) photoelectron peak was recorded at 1303.99 eV, thus confirming the Mg presence in the form of MgO. See National Institute of Standards and Technology (NIST) X-ray photoelectron spectroscopy database, 2007, U.S. Department of Commerce, USA; Seyama, H.; Soma, M. J. Chem. Soc. Faraday Trans 1 1984. 80, 237.

It is worth noting that the MgO content was not revealed in the XRD spectra, which might be due to a low crystalline (amorphous structure) and a negligible fraction of MgO in the whole grown products. This XPS result has a probing area of ˜3 mm in diameter on ZnMgO nanowire arrays. The XPS composition analysis revealed ˜5.2 at. % of Mg, relatively higher than the 3.92 at. % in the TEM EDXS result. This composition deviation is due to the surface deposition of MgO on the ZnMgO nanowires, as well as a typical penetration depth of ˜3-5 atomic layers for the XPS probe.

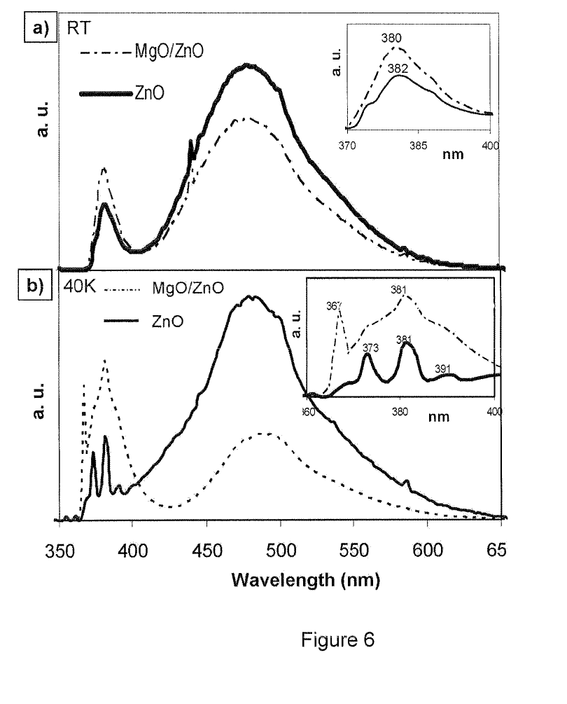

With the successfully alloyed ZnMgO nanowires, the room temperature and low temperature (40K) photoluminescence (PL) properties have been measured by optical pumping to compare with those from pure ZnO nanowire arrays. FIG. 6a shows the room temperature PL spectrum of ZnMgO nanowire arrays compared with that of ZnO nanowire arrays covering a wavelength range of ˜350 to ˜650 nm. Both of them have a strong broad near-blue band peak at ˜482 nm and a near band edge (NBE) ultra-violet (UV) emission peak. The appearance of a broad near-blue band might be due to the existence of defects such as oxygen vacancies in Zn—O lattices for both ZnO and ZnMgO nanowires. See Wang, A.; Dai, J.; Cheng, J.; Chudzik, M. P.; Marks, T. J.; Chang, R. P. H.; Kannewurf, C. R. Appl. Phys. Lett. 1998, 73, 327; See Li, Q. H.; Wan, Q.; Liang, Y. X.; Wang, T. H. Appl. Phys. Lett. 2004, 84, 4556. However, the NBE UV emission peak is centered at 380 nm for the ZnMgO nanowire arrays, which produced a slight blue shift of 2 nm compared to the 382 nm peak observed for ZnO nanowire arrays.

In addition, an enhanced NBE UV emission peak displays in ZnMgO nanowire arrays compared to that of ZnO nanowire arrays. A low temperature (40K) PL result in FIG. 6b revealed a 14-nm blue shift of ZnMgO nanowires compared to that of pure ZnO nanowires, while the NBE emission centered at 381 nm corresponding to ZnO in the PL spectrum for ZnMgO nanowires. This indicated that the alloying of ZnO nanowires with Mg ions might be incomplete in some ZnMgO nanowires, leaving some pure ZnO nanowires as residue. Similar to the room temperature PL results, a much stronger enhancement of UV emission in ZnMgO nanowires was revealed compared to that of ZnO nanowires.

The observed blue shift of UV emission in the ZnMgO nanowires is due to the Mg alloying into ZnO lattice, leading to the widening of the energy band gap. With this result, we further confirmed the success of surface alloying Mg into ZnO nanowire lattice using the low temperature hydrothermal approach. Furthermore, an enhancement in UV emission with a concomitant reduction in near-blue emission in ZnMgO nanowires, might suggest an improved crystallinity and a possible successful reduction of intrinsic defect (such as oxygen vacancy) concentration through the second-step 155° C. “annealing” process. The other possible reason might be due to the surface amorphous layer of MgO, which could be used to produce potential charge transfer events for enhancing the NBE UV emission. See Lin, J. M.; Cheng, C. L.; Lin, H. Y.; Chen, Y. F. Opt. Lett. 2006, 31, 3173.

It is worth noting that, the alloying of Mg into ZnO nanowire lattices is generally difficult to achieve at low temperature processing. However, in example embodiments, the alloying is successfully achieved using a two-step sequential hydrothermal process in spite of a low temperature operation (80° C. and 155° C.). The rationale for this success could be three-fold: 1). The densely packed and vertically grown ZnO nanowire array (FIG. 7a) were the template for the alloying of Mg ions, which might have provided a special localized region to allow the retaining and redistribution of Mg ions surrounding ZnO nanowires; 2). The formation of outside non-continuous, dendrite-like, and near-amorphous MgO would encourage the diffusion of Mg ions to the local nanowire array region (FIG. 7b), therefore promoting more localized retaining and alloying process of Mg ions into neighboring ZnO lattices; 3). The local Zn ion exchange with the existing Zn ion on the ZnO nanowire surface, on the other hand, will further promote the Mg ion substitution with Zn ions, forming the surface alloyed ZnMgO nanowires.

It should be understood that certain processes disclosed herein may be controlled by electronics with certain aspects implemented in hardware, firmware, or software. If implemented in software, the software may be stored on any form of computer readable medium, such as random access memory (RAM), read only memory (ROM), compact disk read only memory (CD-ROM), and so forth. In operation, a general purpose or application specific processor loads and executes the software in a manner well understood in the art.

In summary, large scale ZnMgO nanowire arrays have been successfully synthesized on Si substrates using a two-step sequential hydrothermal synthesis at low temperature for the first time. Based on ZnO nanowire arrays synthesized at 80° C., the successful surface localized alloying of Mg into the ZnO lattices has been achieved through a secondary hydrothermal process at 155° C. The X-ray diffraction analysis indicated a ˜0.1° shift of 2θ in (002) peak of ZnMgO nanowires compared to that of ZnO nanowires, suggesting a successful alloying of Mg into ZnO nanowire lattices after the two-step low-temperature synthesis process. The transmission electron microscopy, scanning transmission electron microscopy, and X-ray photoelectron spectroscopy were systematically carried out. The results further proved that a successful surface localized Mg alloying process was achieved on the densely packed ZnO nanowire arrays during the solution-based low temperature process. Both room temperature and low temperature (40K) photoluminescence results revealed an enhanced and blue-shifted near-band-edge UV emission for the ZnMgO nanowires compared to that of the pure ZnO nanowire arrays. This enhancement might be due to the 155° C. solution-based process and the amorphous structured MgO dendrite branches surrounding the ZnMgO nanowire arrays. The specific template of densely-packed ZnO nanowire arrays was suggested to be crucial in enabling the second-step surface localized alloying of Mg into ZnO lattices. This result could open up a new avenue for low cost and low temperature elemental doping/alloying of nanowire arrays of functional oxides and compound semiconductors, which can potentially bring up new nano-electronics and nano-optoelectronics applications.

### Annealing of Nanowires

Post-annealing processes can be used as an additional optional step to proceed with the solid solution alloying process at high temperature in thin film of semiconductor alloy. Our early work in solution-processed ZnMgO nanowires has indicated the success of alloying process in densely packed ZnO nanowires using low temperature hydrothermal synthesis. The successful alloying process has been confirmed by the blue-shift of 2 nm in UV emission, which, however, is not directly reflected by the ˜4 at. % Mg alloying content revealed from EDXS analysis, which could theoretically lead to a larger blue-shift. With certain processing parameters, incomplete alloying across the radial cross section of ZnO nanowires was achieved in the 2-step sequential hydrothermal synthesis process at low temperature. In order to clarify the surface Mg doping and alloying process, and at the same time investigate the surface coating process of MgO on alloyed ZnO nanowires, a post thermal annealing study has been systematically carried out based on low-temperature solution-processed MgO/ZnMgO nanowire arrays.

The structure evolution occurs due to post thermal annealing at elevated temperatures, leading to formation of different core-shell composite nanowires controlled by different thermal annealing processes. Specifically, slow or rapid annealing processes at high temperature can produce continuous or modulated dendritic amorphous, polycrystalline and single-crystalline Mg-rich oxide layers that can be tuned to surround the ZnMgO nanowire cores, forming important and unique classes of architectures for applications in solar absorption, vertical nanowire transistors, and heterojunction superlattice electronics. Furthermore, the photoluminescence properties vary with the structure changes in the core-shell composite nanowires. It is observed that, with the increasing annealing temperature from 400° C., to 600° C., 700° C., and 800° C., the ultraviolet (UV) near-band-edge (NBE) emission under 325 nm laser excitation at room temperature further blue shifted from 379 nm, to 377 nm, 375 nm and to 372 nm for the annealed ZnMgO nanowire arrays. However, with the increasing annealing temperature from 400° C. to 900° C., the UV NBE emission relative intensity decreases until it disappears for the processed ZnMgO nanowire arrays, despite the enhanced crystallinity of the nanowires.

The decrease and quench of the UV emission might be due to the composite nanowire structure evolution including the Mg-rich oxide and the interface microstructure, while the crystallinity of the nanowires improved resulting in a reduction in the defect-related near blue bands. After the 900° C. annealing process, a thin shell of crystalline Mg-rich oxide was found to epitaxially grow over the ZnMgO nanowire surface that could potentially quench the UV excitation from ZnMgO cores. Furthermore, the nanoscale localization of alloyed nanowires was successfully kept intact through suppressing the slow surface diffusion by using a rapid thermal annealing process. The successful demonstration of controlled nanoscale localized alloying in semiconductor alloy nanowires could bring up new opportunities for novel device applications in optoelectronics, spintronics, and sensors.

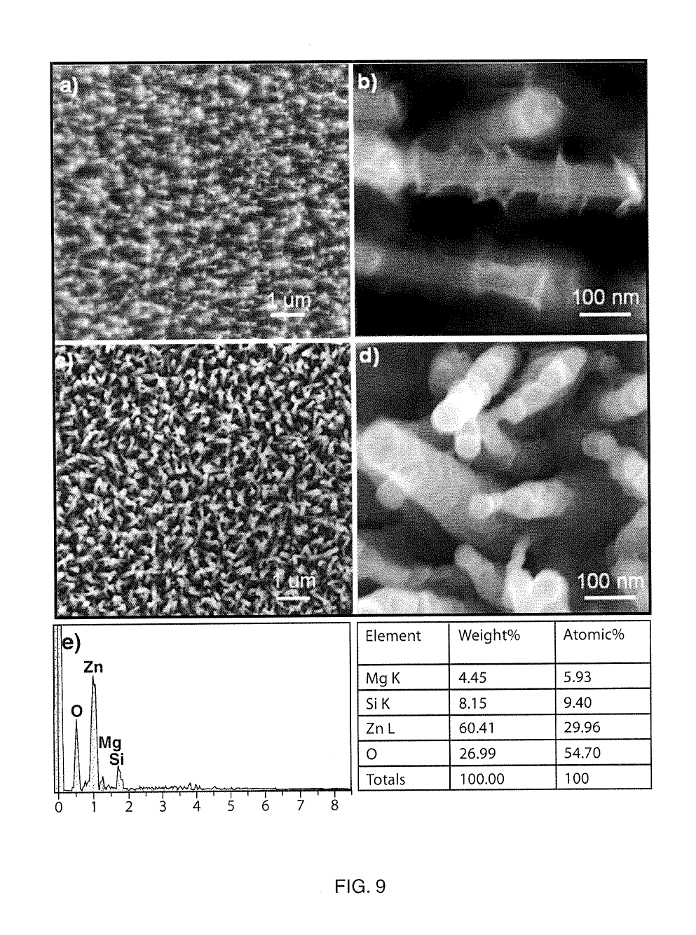

FIG. 9a shows a tilt view SEM image of as-grown nanowire arrays with dendritic branch structures, further illustrated by FIG. 9b. After a 900° C. annealing for 5 minutes, the dendritic nanowire array morphology changed with the array structures kept intact, as displayed in FIGS. 9c and d. The zoom-in image in FIG. 9d showed the ZnMgO nanowires with roughened surface. The EDXS results indicated that through annealing, the Mg concentration in ZnMgO nanowires could be increased from 4 to 8 atomic percent. An example EDXS spectrum and corresponding elemental analysis showing a Mg concentration of 5.93 atomic percent is shown in FIG. 9e.

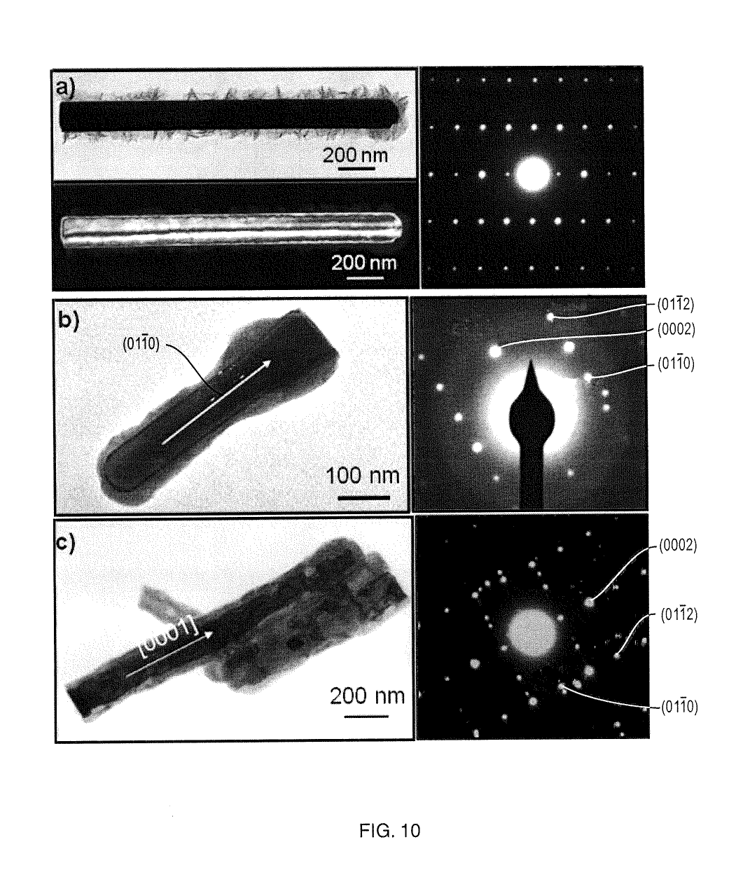

The transmission electron microscopy study on the slowly annealed nanowires suggests that with the annealing temperature increasing from room temperature, to 400° C., and to 900° C., the dendritic surface amorphous MgO (room temperature as-received ZnMgO nanowire, FIG. 10a) could be turned into a continuous thin shell of amorphous MgO (400° C. annealing, FIG. 10b), and further into single-crystalline core-shell nanowire (900° C. annealing, FIG. 10c). The selected area electron diffraction patterns in FIGS. 10a, 10b, and 10c confirmed the core ZnMgO nanowire, and the shell crystal structure evolution from amorphous to single crystalline. These types of core-shell composite nanowires with different crystallinity control over the coating could be very helpful to the enhancement of light absorption and then solar energy harvesting. In addition, they could be potential candidate building blocks for nanoscale core-shell transistors with MgO as the candidate gate dielectrics.

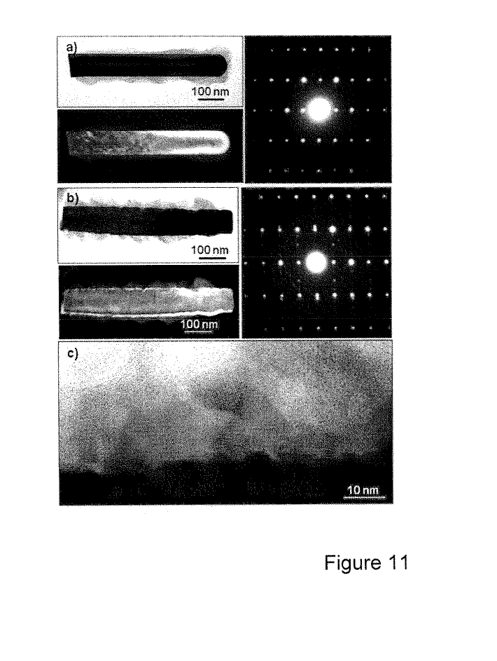

As inspired by the chemically modulated superlattice nanofilms, a rapid thermal annealing was successfully used to keep the dendritic distribution of MgO shell on ZnMgO nanowires, forming unique superlattice heteronanowire architectures as confirmed by the TEM images and diffraction analysis shown in FIG. 11. FIG. 11a is a typical TEM image showing the ZnMgO nanowires surrounded by dendritic amorphous MgO after 400° C. annealing for 30 minutes, where the modulated structure seemed to be kept intact. After 800° C. rapid thermal annealing for 5 minutes, the dendritic surface layer transformed into dendritic polycrystal, as indicated in the SAED in FIG. 11b and the high resolution TEM (HRTEM) image in FIG. 11c.

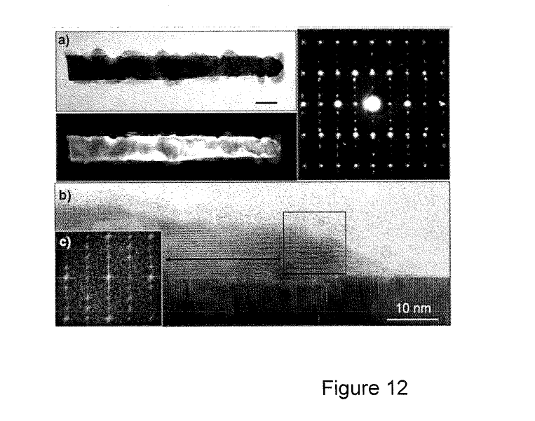

Further annealing at higher temperature such as 900° C. could turn the modulated polycrystalline surface layer into single crystalline “textured” nano-islands epitaxially overcoated on ZnMgO nanowire, as shown in FIG. 12. The SAED pattern in FIG. 12a and the HRTEM image in FIG. 12b clearly indicate the formation of Mg-rich oxide nano-islands epitaxially extended from the core ZnMgO nanowire lattices. These modulated dendritic core-shell hetero-nanowires could be used as a new type of chemically modulated superlattices along the nanowire surfaces, with potential applications in nanolasers, nanosensors, and nanomemories depending on different alloying elements, such as, for example, Mn, Cu, Cd, Co, Be, and Fe.

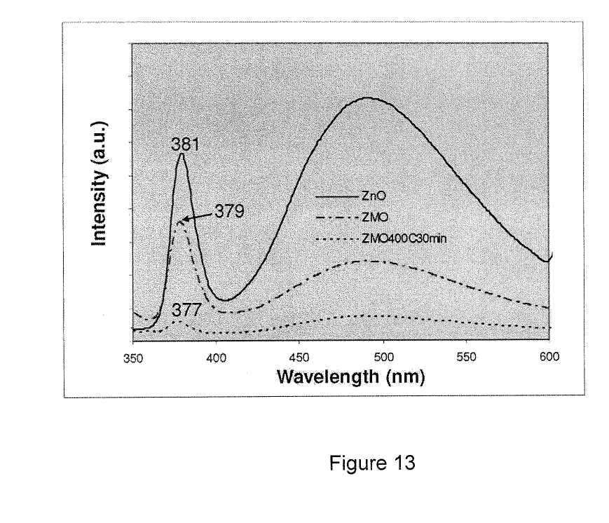

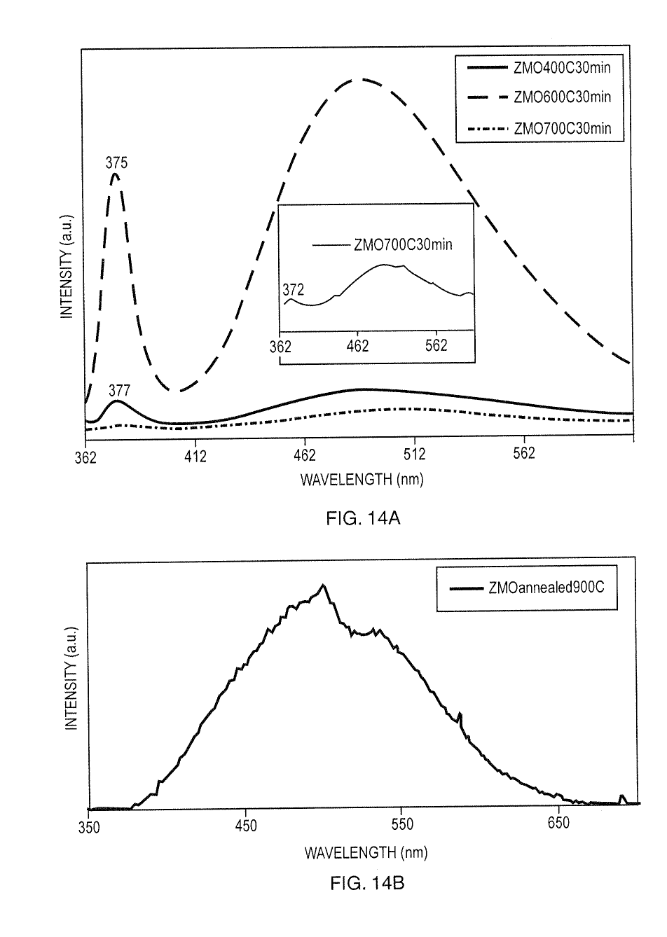

The room temperature photoluminescence study on the annealed samples has been carried out to investigate the annealing effect on the surface alloying process of ZnMgO nanowires. FIGS. 13 and 14 are the results collected and plotted with photoluminescence intensity as a function of wavelength. The relative intensity of NBE UV emission is identified as I_{NBE}/I_{GE} (NBE: near-band-edge emission; GE: defect-related green emission). FIGS. 13 and 14 illustrate that, as the annealing temperature increases, the blue shift of NBE became more significant, resulting in the NBE peak position shift from 379 (as-grown ZnMgO nanowires, compared to 381 nm emission in ZnO nanowires), to 377 nm (400° C. annealing, 30 minutes), to 375 nm (600° C. annealing, 30 minutes), to 372 nm (700° C. annealing, 30 minutes). Furthermore, the relative intensity of NBE UV emission decreases gradually from 1.486, 0.800, 0.735, 0.491 with the increasing of annealing temperature from room temperature, 400° C., 600° C., to 700° C., and is completely quenched after annealing at 900° C.

TABLE 1
X-ray diffraction data on the annealed
ZnMgO nanowire arrays samples.

| NW Arrays | FWHM | (002) peak |
|---|---|---|
| ZnO | 0.213 | 34.451 |
| ZnMgO | 0.188 | 34.512 |
| ZnMgO | 0.218 | 34.471 |
| (400° C. annealed) | | |
| ZnMgO | 0.222 | 34.461 |
| (600° C. annealed) | | |
| ZnMgO | 0.223 | 34.430 |
| (800° C. annealed) | | |

(NW: nanowire; FWHM: full width at half maximum)

To further unravel the structure evolution during the thermal annealing processes, x-ray diffraction analysis has also been conducted. As shown in Table 1, the (002) peak has been identified for each spectrum collected from ZnMgO nanowire arrays samples after annealing at different temperatures ranging from 400° C. to 800° C. Their full width at half maximum (FWHM) in (002) peaks and the 2θ angles have been recorded for comparison. It is clearly seen that after annealing, the FWHM increased as a result of the increasing polycrystalline portion of the outer Mg-rich oxide shells, leading to smaller overall average crystal size. On the other hand, the 2θ angles decreased with the increasing annealing temperature, which might suggest the possible influence from strain induced lattice expansion in ZnMgO nanowire core along the [002] direction as a result of the enhanced shell crystallinity and the texture structure after 800-900° C. annealing, as evidenced by the textured crystalline Mg-rich oxide (large lattice constant) epitaxially grown on ZnMgO nanowire shown in FIG. 12.

The increasing blue shift of NBE UV emission with increasing annealing temperature should be due to the thermally annealing induced further alloying of Mg into the ZnMgO nanowires as-grown from the 2-step sequential hydrothermal synthesis, as evidenced by EDXS results in FIG. 9e. The Mg ion source for further alloying upon annealing is due to the amorphous MgO nanoshell. The decreasing relative NBE UV emission intensity with increasing annealing temperature might be due to the quenching effect from the surface textured Mg-rich oxide layer.

In summary, the localized alloying of Mg ions into ZnO nanowire lattices through thermal annealing has been systematically studied on low-temperature solution-processed ZnMgO nanowire arrays. The structure evolution due to post thermal annealing at elevated temperatures was revealed to be responsible for variations in the photoluminescence properties. With increasing annealing temperature from 400° C., 600° C., 700° C., to 800° C., the UV NBE emission of ZnMgO nanowire arrays under 325 nm laser excitation at room temperature further blue shifted from 379 nm, 377 nm, 375 nm to 372 nm. On the other hand, with the increasing annealing temperature from 400° C. to 900° C., the UV NBE emission relative intensity decreased until it disappeared for the processed ZnMgO nanowire arrays, despite the enhanced crystallinity of the nanowires. The annealing induced polycrystalline and single crystalline MgO layer surrounding the ZnMgO nanowire might be the reason of decaying and quenching of the UV NBE emission. The nanoscale localization of alloyed nanowires coated with either continuous shell or modulated nano-islands could be successfully controlled through either a slow thermal annealing process or a rapid thermal annealing process, leading to new classes of functional nanobuilding blocks for various applications including electronics, optoelectronics, spintronics, and sensors.

### Applications of Nanowires

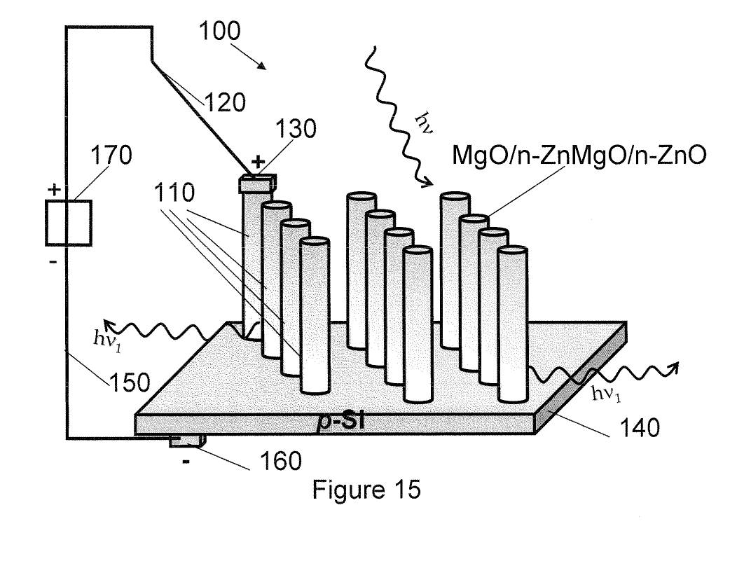

An example embodiment of a light emitting diode (LED) including nanowires according to an embodiment of the invention is illustrated in FIG. 15. Turning to LED 100 illustrated in FIG. 15, a junction between n-type ZnO/n-ZnMgO/MgZnO/MgO 110 and p-Si 140 forms a multiple band-offset heterojunction diode, leading to a different emission wavelength (variable hν₁) upon energetic optical (hν), where ν>ν₁ excitation, or upon electrical excitation by flowing a current through positive connection lead 120 to the positive electrical contact 130 and negative connection lead 150 to the negative electrical contact 160. A load or battery 170, in the case of a solar cell application or an LED application, respectively, is electrically disposed between the electrical contacts 130, 160. It should be understood that the positive electrical contact 130 is in contact with each nanowire 110.

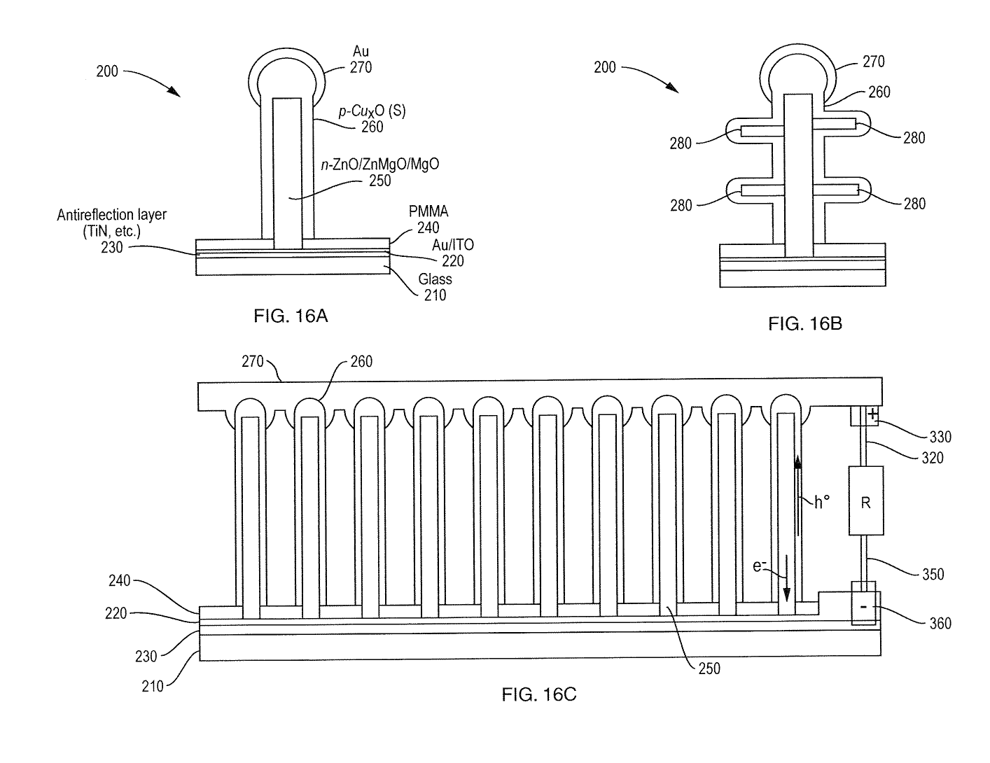

An example embodiment of a solar cell, where the solar radiation input is from the bottom electrode, and including nanowires according to the invention is illustrated in FIG. 16. An example of a solar cell 200 including ZnO/MgZnO/MgO/CuₓO (x=1 or 2) or ZnO/CuZnO/Cu₂O gradient nanowire arrays is illustrated in FIG. 16a). A glass substrate 210 can be coated with a layer of gold and indium tin oxide (Au/ITO) 220, followed by an antireflection layer 230, such as, for example, titanium nitride (TiN), followed by a layer of a polymer 240, such as polymethyl methacrylate (PMMA). When the nanowire/dendrite array is sufficiently dense, then the PMMA insulation layer or dielectric space for supporting the device structure can be omitted. The nanowire of n-ZnO/ZnMgO/MgO 250 is connected to the Au/ITO layer 220 and coated with a layer of p-CuₓO 260 (x=1 or 2). The other terminal 270 is located at the distal end of the nanowire 250. The solar cell 200 can include gradient nanodendrite arrays 280, as illustrated in FIG. 16b). A prototype device schematic for gradient nanowire solar cell arrays is illustrated in FIG. 16c), including the positive connection lead 320 to the positive electrical contact 330 and negative connection lead 350 to the negative electrical contact 360.

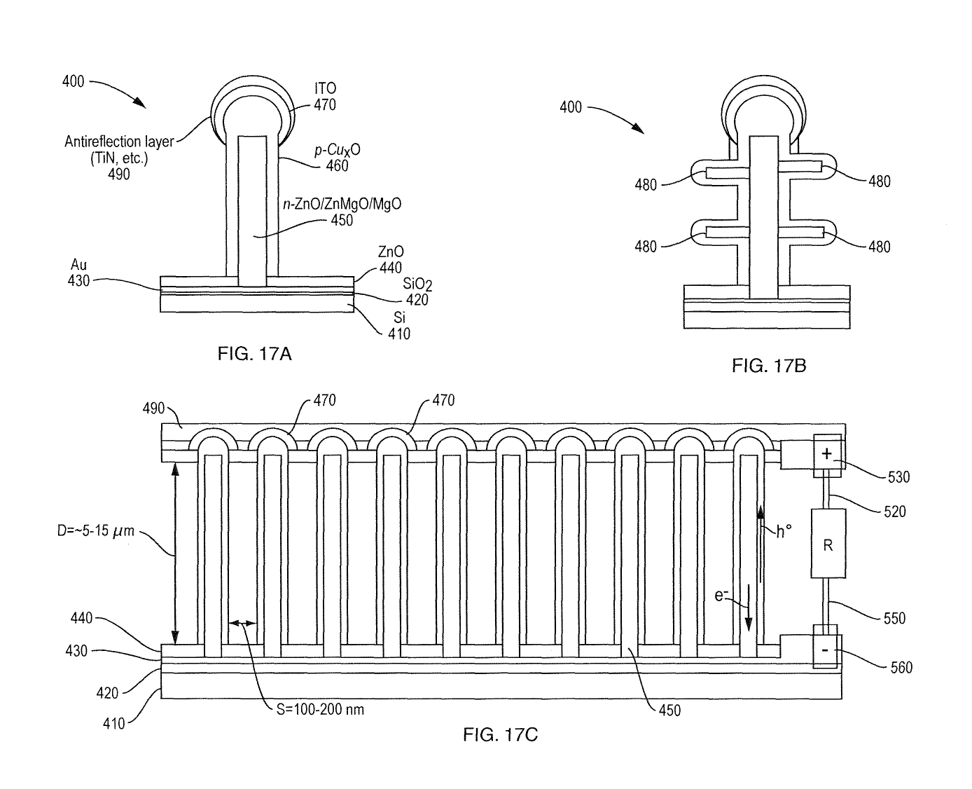

Another example embodiment of a solar cell, where the solar radiation input is from the top electrode, and including nanowires according to the invention is illustrated in FIG. 17. An example of a solar cell 400 including ZnO/MgZnO/MgO/CuₓO (x=1 or 2) or ZnO/CuZnO/Cu₂O gradient nanowire arrays is illustrated in FIG. 17a). A silicon substrate 410 can be coated with a layer of silicon dioxide 420, followed by a layer of gold 430, followed by a layer of ZnO 440. The nanowire of n-ZnO/ZnMgO/MgO 450 is connected to the Au layer 430 and coated with a layer of p-CuₓO 460 (x=1 or 2). The other terminal 470, made of indium tin oxide (ITO) is located at the distal end of the nanowire 450. The solar cell 400 can include gradient nanodendrite arrays 480, as illustrated in FIG. 17b). A prototype device schematic for gradient nanowire solar cell arrays is illustrated in FIG. 17c), including the positive connection lead 520 to the positive electrical contact 530 and negative connection lead 550 to the negative electrical contact 560.

The relevant teachings of all patents, published applications and references cited herein are incorporated by reference in their entirety.

While this invention has been particularly shown and described with references to example embodiments thereof, it will be understood by those skilled in the art that various changes in form and details may be made therein without departing from the scope of the invention encompassed by the appended claims.

What is claimed is:

1. A method of producing a uniform nanowire array, the method comprising:
a) growing an array of two-element nanowires; and
b) uniformly doping or alloying each two-element nanowire, with respect to each other two-element nanowire, with at least one doping or alloying element, through a wet chemical synthesis with a precursor solution to produce a uniform array of at least three-element nanowires.

2. The method of claim 1 wherein growing the array of two-element nanowires further includes uniformly varying a characteristic of each two-element nanowire, the characteristic being at least one of a group consisting of physical dimensions, processing time, temperature, packing density, energy band-gap, and composition of each two-element nanowire.

3. The method of claim 1 wherein growing the array of two-element nanowires includes seeded growing of the array of two-element nanowires.

4. The method of claim 1 wherein growing the array of two-element nanowires further includes performing a hydrothermal or solvathermal synthesis.

5. The method of claim 1 wherein uniformly doping or alloying each two-element nanowire further includes uniformly controlling a concentration and band-gap of each at least three-element nanowire by varying a fabrication parameter selected from a group consisting of temperature, processing time, pH and pressure.

6. The method of claim 1 wherein uniformly doping or alloying each two-element nanowire further includes uniformly controlling a concentration of each element of each at least three-element nanowire.

7. The method of claim 1 wherein the wet chemical synthesis is a hydrothermal or solvathermal synthesis performed at a temperature of less than 300° C.

8. The method of claim 7 wherein the hydrothermal or solvathermal synthesis is performed at a temperature in a range of between about 100° C. and about 200° C.

9. The method of claim 1 wherein the two-element nanowire comprises Zn and O and the at least one doping or alloying element is at least one of a group consisting of Mg, Cd, Mn, Cu, Be, Fe, and Co.

10. The method of claim 1 wherein the two-element nanowire comprises Cu and O and the at least one doping or alloying element is at least one of a group consisting of Zn, Mg, Cd, Be, Fe, and Co.

11. The method of claim 1 wherein the two-element nanowire comprises Cd and O and the at least one doping or alloying element is at least one of a group consisting of Mg, Zn, Mn, Cu, Be, Fe, and Co.

12. The method of claim 1 wherein the two-element nanowire comprises Mg and O and the at least one doping or alloying element is at least one of a group consisting of Zn, Cd, Mn, Cu, Be, Fe, and Co.

13. The method of claim 1 wherein the two-element nanowire comprises Fe and O and the at least one doping or alloying element is at least one of a group consisting of Zn, Cd, Mn, Cu, Mg, Be, and Co.

14. The method of claim 1 wherein the two-element nanowire comprises Be and O and the at least one doping or alloying element is at least one of a group consisting of Zn, Cd, Mn, Cu, Fe, Mg, and Co.

15. The method of claim 1 wherein the two-element nanowire comprises Mn and O and the at least one doping or alloying element is at least one of a group consisting of Zn, Cd, Cu, Fe, Mg, Be, and Co.

16. The method of claim 1 further including the step of annealing the uniform nanowire array of at least three-element nanowires.

17. The method of claim 16, wherein the step of annealing is performed at a temperature in a range of between about 200° C. and about 1000° C., for a time period in a range of between about 5 minutes and about 10 hours.

18. The method of claim 1 wherein uniformly doping or alloying each two-element nanowire is performed by uniformly doping or alloying each two-element nanowire with the doping or alloying element with respect to a radial cross section of each two-element nanowire.

19. A system for providing a uniform nanowire array, the system comprising:
a first module configured to grow an array of two-element nanowires;
a second module configured to prepare a precursor solution including at least one doping or alloying element and a base; and
a third module configured to provide a uniform nanowire array by using a wet chemical synthesis with the precursor solution, to provide an at least three-element nanowire array including a uniform composition distribution.

20. The system of claim 19 wherein the first module further includes uniformly varying a characteristic of each two-element nanowire, the characteristic being at least one of a group consisting of physical dimensions, processing time, temperature, packing density, energy band-gap, and composition of each two-element nanowire.

21. The system of claim 19 wherein the first module further includes a seeded growing of the array of two-element nanowires.

22. The system of claim 19 wherein the first module further includes a hydrothermal or solvathermal synthesis module.

23. The system of claim 19 wherein the uniform composition distribution is achieved by controlling a concentration and band-gap of each at least three-element nanowire by varying a fabrication parameter selected from a group consisting of temperature, processing time, pH and pressure.

24. The system of claim 19 wherein the uniform composition distribution is achieved by controlling a concentration of each element of each at least three-element nanowire.

25. The system of claim 19 wherein the wet chemical synthesis is a hydrothermal or solvathermal synthesis performed at a temperature of less than 300° C.

26. The system of claim 25 wherein the hydrothermal or solvathermal synthesis is performed at a temperature in a range of between about 100° C. and about 200° C.

27. The system of claim 19 wherein the two-element nanowire comprises Zn and O and the at least one doping or alloying element is at least one of a group consisting of Mg, Cd, Mn, Cu, Be, Fe, and Co.

28. The system of claim 19 wherein the two-element nanowire comprises Cu and O and the at least one doping or alloying element is at least one of a group consisting of Zn, Mg, Cd, Be, Fe, Mn, and Co.

29. The system of claim 19 wherein the two-element nanowire comprises Cd and O and the at least one doping or alloying element is at least one of a group consisting of Mg, Zn, Mn, Cu, Be, Fe, and Co.

30. The system of claim 19 wherein the two-element nanowire comprises Mg and O and the at least one doping or alloying element is at least one of a group consisting of Zn, Cd, Mn, Cu, Be, Fe, and Co.

31. The method of claim 19 wherein the two-element nanowire comprises Fe and O and the at least one doping or alloying element is at least one of a group consisting of Zn, Cd, Mn, Cu, Mg, Be, and Co.

32. The method of claim 19 wherein the two-element nanowire comprises Be and O and the at least one doping or alloying element is at least one of a group consisting of Zn, Cd, Mn, Cu, Fe, Mg, and Co.

33. The method of claim 19 wherein the two-element nanowire comprises Mn and O and the at least one doping or alloying element is at least one of a group consisting of Zn, Cd, Cu, Fe, Mg, Be, and Co.

34. The system of claim 19 further including the step of annealing the uniform nanowire array.

35. The system of claim 34 further including annealing the uniform nanowire array at a temperature in a range of between about 200° C. and about 1000° C., for a time period in a range of between about 5 minutes and about 10 hours.

36. The system of claim 19 wherein the uniform composition distribution is achieved by uniformly doping or alloying each two-element nanowire with the doping or alloying element with respect to a radial cross section of each two-element nanowire.

37. A method of producing a uniform nanowire array, the method comprising:
uniformly doping or alloying each two-element nanowire of a two-element nanowire array with at least a third element through a wet chemical synthesis with the precursor solution, to form an array of at least three-element nanowires.

38. The method of claim 37 wherein uniformly doping or alloying each two-element nanowire further includes uniformly controlling a concentration and band-gap of each at least three-element nanowire by varying a fabrication parameter selected from the group consisting of temperature, processing time, pH and pressure.

39. The method of claim 37 wherein uniformly doping or alloying each two-element nanowire further includes uniformly controlling a concentration of each element of each at least three-element nanowire.

40. The method of claim 37 wherein the wet chemical synthesis is a hydrothermal or solvathermal synthesis performed at a temperature of less than 300° C.

41. The method of claim 40 wherein the hydrothermal or solvathermal synthesis is performed at a temperature in a range of between about 100° C. and about 200° C.

42. The method of claim 37 wherein the two-element nanowire comprises Zn and O and the at least third element is at least one of a group consisting of Mg, Cd, Mn, Cu, Be, Fe, and Co.

43. The method of claim 37 wherein the two-element nanowire comprises Cu and O and the at least third element is at least one of a group consisting of Zn, Mg, Cd, Be, Fe, Mn, and Co.

44. The method of claim 37 wherein the two-element nanowire comprises Cd and O and the at least third element is at least one of a group consisting of Mg, Zn, Mn, Cu, Be, Fe, and Co.

45. The method of claim 37 wherein the two-element nanowire comprises Mg and O and the at least third element is at least one of a group consisting of Zn, Cd, Mn, Cu, Be, Fe, and Co.

46. The method of claim 37 wherein the two-element nanowire comprises Fe and O and the at least third element is at least one of a group consisting of Zn, Cd, Mn, Cu, Mg, Be, and Co.

47. The method of claim 37 wherein the two-element nanowire comprises Be and O and the at least third element is at least one of a group consisting of Zn, Cd, Mn, Cu, Fe, Mg, and Co.

48. The method of claim 37 wherein the two-element nanowire comprises Mn and O and the at least third element is at least one of a group consisting of Zn, Cd, Cu, Fe, Mg, Be, and Co.

49. The method of claim 37 further including the step of annealing the uniform nanowire array.

50. The method of claim 49 further including annealing the uniform nanowire array at a temperature in a range of between about 200° C. and about 1000° C., for a time period in a range of between about 5 minutes and about 10 hours.

51. The method of claim 37, wherein uniformly doping or alloying each two-element nanowire is performed by uniformly doping each two-element nanowire with the third element with respect to a radial cross section of each two-element nanowire.

52. A uniform nanowire array comprising a plurality of nanowires including at least three elements, each nanowire being uniform with respect to a concentration of the at least three-elements in a radial cross section.

53. The uniform nanowire array of claim 52 wherein uniformity is achieved by controlling a concentration and band-gap of each of the at least three-elements by varying a fabrication parameter selected from a group consisting of temperature, processing time, pH and pressure.

54. The uniform nanowire array of claim 52 wherein the at least three-elements include Zn, O, and Mg.

55. The uniform nanowire array of claim 52 wherein the at least three elements include Zn and O and at least one of a group consisting of Mg, Cd, Mn, Be, Fe, and Co.

56. The uniform nanowire array of claim 52 wherein the at least three elements include Cu and O and at least one of a group consisting of Zn, Mg, Cd, Be, Fe, Mn, and Co.

57. The uniform nanowire array of claim 52 wherein the at least three elements include Cd and O and at least one of a group consisting of Mg, Zn, Mn, Cu, Be, Fe, and Co.

58. The uniform nanowire array of claim 52 wherein the at least three elements include Mg and O and at least one of a group consisting of Zn, Cd, Mn, Cu, Be, Fe, and Co.

59. The method of claim 52 wherein the at least three elements include Fe and O and at least one of a group consisting of Zn, Cd, Mn, Cu, Mg, Be, and Co.

60. The method of claim 52 wherein the at least three elements include Be and O and at least one of a group consisting of Zn, Cd, Mn, Cu, Fe, Mg, and Co.

61. The method of claim 52 wherein the at least three elements include Mn and O and at least one of a group consisting of Zn, Cd, Cu, Fe, Mg, Be, and Co.

62. A uniform nanowire array, said array produced by the process of:
a) growing a uniform array of two-element nanowires;
b) mixing a solution of chemical precursors including at least one doping element and a base;
c) disposing the array of two-element nanowires in the solution; and
d) heating the disposed array of two-element nanowires in a manner uniformly doping or alloying the array of two-element nanowires with the at least one doping or alloying element, to form a uniform array of at least three-element nanowires.

63. The uniform nanowire array of claim 62 wherein growing the array of two-element nanowires further includes uniformly varying a characteristic of each two-element nanowire, the characteristic being at least one of a group consisting of physical dimensions, processing time, temperature, packing density, energy, band-gap and composition of each two-element nanowire.

64. The uniform nanowire array of claim 62 wherein growing the array of two-element nanowires includes a seeded growing of the array of two-element nanowires.

65. The uniform nanowire array of claim 62 wherein growing the array of two-element nanowires further includes performing a hydrothermal or solvathermal synthesis.

66. The uniform nanowire array of claim 62 wherein uniformly doping or alloying each two-element nanowire further includes uniformly controlling concentration and band-gap of each at least three-element nanowire by varying a fabrication parameter selected from a group consisting of temperature, processing time, pH and pressure.

67. The uniform nanowire array of claim 62 wherein heating is performed at a temperature of less than 300° C.

68. The uniform nanowire array of claim 67 wherein heating is performed at a temperature in a range of between about 100° C. and about 200° C.

69. The uniform nanowire array of claim 62 wherein the two-element nanowire comprises Zn and O and the at least one doping or alloying element is at least one of a group consisting of Mg, Cd, Mn, Cu, Be, Fe, and Co.

70. The uniform nanowire array of claim 62 wherein the two-element nanowire comprises Cu and O and the at least one doping or alloying element is at least one of a group consisting of Zn, Mg, Cd, Be, Fe, Mn, and Co.

71. The uniform nanowire array of claim 62 wherein the two-element nanowire comprises Cd and O and the at least one doping or alloying element is at least one of a group consisting of Mg, Zn, Mn, Cu, Be, Fe, and Co.

72. The uniform nanowire array of claim 62 wherein the two-element nanowire comprises Mg and O and the at least one doping or alloying element is at least one of a group consisting of Zn, Cd, Mn, Cu, Be, Fe, and Co.

73. The method of claim 62 wherein the two-element nanowire comprises Fe and O and the at least one doping or alloying element is at least one of a group consisting of Zn, Cd, Mn, Cu, Mg, Be, and Co.

74. The method of claim 62 wherein the two-element nanowire comprises Be and O and the at least one doping or alloying element is at least one of a group consisting of Zn, Cd, Mn, Cu, Fe, Mg, and Co.

75. The method of claim 62 wherein the two-element nanowire comprises Mn and O and the at least one doping or alloying element is at least one of a group consisting of Zn, Cd, Cu, Fe, Mg, Be, and Co.

76. The uniform nanowire array of claim 62 further including the step of annealing the uniform nanowire array.

77. The uniform nanowire array of claim 76 further including annealing the uniform nanowire array at a temperature in a range of between about 200° C. and about 1000° C., for a time period in a range of between about 5 minutes and about 10 hours.

78. The uniform nanowire array of claim 62 wherein uniformly doping each two-element nanowire is performed by uniformly doping or alloying each two-element nanowire with the doping element with respect to a radial cross section of each two-element nanowire.

79. A solar cell device comprising at least one layer including a uniform three-element nanowire array having uniform three-element nanowires with respect to each other nanowire in terms of chemical composition.

80. The solar cell device of claim 79 wherein the elements include Zn, O and Mg.

81. An electronic device comprising a plurality of nanowires defining a junction of the device, each nanowire including a uniform concentration of at least three elements.

82. The electronic device of claim 81, further including leads configured to carry electrons to or from the junction to enable the electronic device to convert electrons to photons or photons to electrons.

83. The electronic device of claim 81 wherein the three elements include Zn, O and Mg.

84. The electronic device of claim 81 wherein the device is an optoelectronic device.
